(19) United States
(12) Patent Application Publication
(10) Pub. No.: US 2025/0318051 A1
(43) Pub. Date: Oct. 9, 2025

(54) WIRING CIRCUIT BOARD

(71) Applicant: NITTO DENKO CORPORATION, Osaka (JP)

(72) Inventors: Ikuya HASHIMOTO, Osaka (JP); Takashi YAMAMOTO, Osaka (JP); Ryosuke SASAOKA, Osaka (JP)

(73) Assignee: NITTO DENKO CORPORATION, Osaka (JP)

(21) Appl. No.: 19/092,788

(22) Filed: Mar. 27, 2025

(30) Foreign Application Priority Data
Apr. 5, 2024 (JP) 2024-061771
Feb. 5, 2025 (JP) 2025-017776

(51) Int. Cl. H05K 1/11

(52) U.S. Cl. CPC H05K 1/111; H05K 2201/0183; H05K 2201/09045; H05K 2201/09236; H05K 2201/09381

(57) ABSTRACT

A wiring circuit board includes a first insulating layer, a circuit pattern, a second insulating layer, and a third insulating layer. The circuit pattern includes a first terminal, a first wire connected to the first terminal, and a second terminal spaced apart from the first terminal. The first wire includes a first body portion covered with the second insulating layer, and a first exposed portion disposed between the first terminal and the first body portion and exposed from the second insulating layer. The third insulating layer is disposed between the first exposed portion and the second terminal, and is disposed between the first terminal and the second terminal.

### CROSS-REFERENCE TO RELATED APPLICATION

The present application claims priority from Japanese Patent Application No. 2024-061771 filed on Apr. 5, 2024, and priority from Japanese Patent Application No. 2025-17776 filed on Feb. 5, 2025, the contents of both of which are hereby incorporated by reference into this application.

### TECHNICAL FIELD

The present invention relates to a wiring circuit board.

### BACKGROUND ART

Conventionally, there has been known a wiring circuit board including a base insulating layer, a conductor layer, and a cover insulating layer covering the conductor layer. The conductor layer includes a plurality of terminal portions and a plurality of wires. The cover insulating layer covers a plurality of wires (for example, see Patent Document 1 below).

### CITATION LIST

### Patent Document

Patent Document 1: Japanese Unexamined Patent Publication No. 2022-002248

### SUMMARY OF THE INVENTION

### Problem to Be Solved by the Invention

In the wiring circuit board described in Patent Document 1 described above, when the fine pitch further advances, and the solder which is molten on the terminal portion flows toward an adjacent terminal portion, there is a possibility that the adjacent terminals are short-circuited through the solder.

The present invention provides a wiring circuit board capable of suppressing a short circuit between the first terminal and the second terminal caused by the solder.

### Means for Solving the Problem

The present invention [1] includes a wiring circuit board including: a first insulating layer; a circuit pattern disposed on the first insulating layer and including a first terminal, a first wire connected to the first terminal, and a second terminal spaced apart from the first terminal; a second insulating layer disposed on the first insulating layer and covering the first wire; and a third insulating layer disposed on the first insulating layer, wherein the first wire includes a first body portion covered with the second insulating layer, and a first exposed portion disposed between the first terminal and the first body portion and exposed from the second insulating layer, and wherein the third insulating layer is disposed between the first exposed portion and the second terminal, and disposed between the first terminal and the second terminal.

According to such a configuration, the third insulating layer is disposed between the first exposed portion and the second terminal, and is disposed between the first terminal and the second terminal.

Therefore, even when the solder placed on the first terminal melts, and the molten solder flows from the first terminal and the first exposed portion toward the second terminal, the molten solder can be stopped by the third insulating layer.

As a result, it is possible to suppress a short circuit between the first terminal and the second terminal caused by the solder.

The present invention [2] includes the wiring circuit board described in the above-described [1], wherein the circuit pattern further includes a second wire connected to the second terminal, wherein the second wire includes a second body portion covered with the second insulating layer, and a second exposed portion disposed between the second terminal and the second body portion and exposed from the second insulating layer, and wherein the third insulating layer is disposed between the first exposed portion and the second exposed portion.

According to such a configuration, even when the solder flowing along the first exposed portion flows toward the second exposed portion, the molten solder can be stopped by the third insulating layer.

As a result, it is possible to suppress a short circuit between the first exposed portion and the second exposed portion caused by the solder.

The present invention [3] includes the wiring circuit board described in the above-described [1] or [2], wherein the third insulating layer is continuous with the second insulating layer.

According to such a configuration, the solder flowing from the first exposed portion can surely be stopped.

The present invention [4] includes the wiring circuit board described in any one of the above-described [1] to [3], wherein the first terminal includes: a first conductor layer disposed on the first insulating layer; and a second conductor layer disposed on the first conductor layer.

The present invention [5] includes the wiring circuit board described in the above-described [4], wherein the second conductor layer protrudes toward an opposite side to the first insulating layer with respect to the first conductor layer in the thickness direction of the first insulating layer, as compared with the second insulating layer.

The present invention [6] includes the wiring circuit board described in any one of the above-described [1] to [5], wherein the third insulating layer is disposed away from the first terminal and the second terminal.

The present invention [7] includes the wiring circuit board described in any one of the above-described [1] to [6], wherein the first exposed portion extends in a direction orthogonal to a direction in which the first terminal and the second terminal are arranged.

According to such a configuration, when the solder placed on the first terminal melts, the molten solder may flow along the first exposed portion.

In this regard, the first exposed portion extends in a direction orthogonal to a direction in which the first terminal and the second terminal are arranged.

Therefore, the molten solder can be guided into the direction orthogonal to the direction in which the first terminal and the second terminal are arranged.

As a result, it is possible to suppress the flow of the molten solder toward the second terminal.

The present invention [8] includes the wiring circuit board described in any one of the above-described [1] to [7], wherein a width of the first exposed portion is narrower than a width of the first terminal.

According to such a configuration, even when the molten solder flows along the first exposed portion, the flowing solder can be concentrated in a range narrower than the width of the first terminal.

As a result, it is possible to suppress the flow of the molten solder toward the second terminal.

The present invention [9] includes the wiring circuit board described in any one of the above-described [1] to [8], including: a flexible portion in which at least a part of the first wire is disposed; and a support portion that supports the flexible portion, wherein the support portion includes a metal support layer, and wherein the flexible portion does not include the metal support layer.

### Effects of the Invention

According to the wiring circuit board of the present invention, it is possible to suppress a short circuit between the first terminal and the second terminal by the solder.

### BRIEF DESCRIPTION OF THE DRAWINGS

FIG. 1 is a plan view of one embodiment of a wiring circuit board of the present invention.

FIG. 2A is a cross-sectional view of the wiring circuit board shown in FIG. 1, taken along line A-A. FIG. 2 B is a cross-sectional view of the wiring circuit board shown in FIG. 1, taken along line B-B.

FIG. 3 is a plan view of a wiring circuit board of a modified example (1).

FIG. 4 is a plan view of a wiring circuit board of a modified example (2).

FIG. 5 is a plan view of a wiring circuit board of a modified example (3).

FIG. 6 is a plan view of a wiring circuit board of a modified example (4).

FIG. 7 is a plan view of a wiring circuit board of a modified example (5).

FIG. 8 is a plan view of a wiring circuit board of a modified example (6), and shows an embodiment in which the width of the first exposed portion of the wire is the same as the width of the terminal.

FIG. 9 is a plan view of the wiring circuit board of the modified example (6), and shows an embodiment in which the width of the first exposed portion of the wire is larger than the width of the terminal.

FIG. 10 is a plan view of a wiring circuit board of a modified example (7), and shows an embodiment in which the third insulating layer has a tapered shape.

FIG. 11 is a plan view of the wiring circuit board of the modified example (7), and shows an embodiment in which the third insulating layer has a parabolically tapered shape.

FIG. 12 is a cross-sectional view of a wiring circuit board of a modified example (8), and shows an embodiment in which the third insulating layer covers the edge of the terminal.

FIG. 13 is a cross-sectional view of the wiring circuit board of the modified example (8), and shows an embodiment in which the third insulating layer is formed from a plurality of insulating layers.

FIG. 14 is a cross-sectional view of a wiring circuit board according to a modified example (9).

FIG. 15 is a cross-sectional view of a wiring circuit board of a modified example (11).

FIG. 16 is a cross-sectional view of a wiring circuit board of a modified example (12).

FIGS. 17A of 17C are cross-sectional views of a wiring circuit board of a modified example (13). FIG. 17A shows an embodiment in which the wiring circuit board shown in FIG. 2B does not include a metal support layer. FIG. 17B shows an embodiment in which the wiring circuit board shown in FIG. 15 does not include a metal support layer. FIG. 17C shows an embodiment in which a wiring circuit board shown in FIG. 16 does not include a metal support layer.

FIG. 18A is a plan view of a wiring circuit board of a modified example (14), and shows an embodiment in which the second terminal and the third conductor layer are electrically connected through the second wire. FIG. 18B is a plan view of the wiring circuit board of the modified example (14), and shows an embodiment in which the second terminal and the third conductor layer are directly connected.

FIG. 19 is a plan view of a wiring circuit board of a modified example (15).

FIG. 20 is a plan view of a wiring circuit board of a modified example (16).

FIG. 21 is a cross-sectional view of a wiring circuit board shown in FIG. 20, taken along line C-C.

FIG. 22 is a cross-sectional view of a wiring circuit board of a modified example (17).

### DESCRIPTION OF THE EMBODIMENT

### 1. Wiring Circuit Board

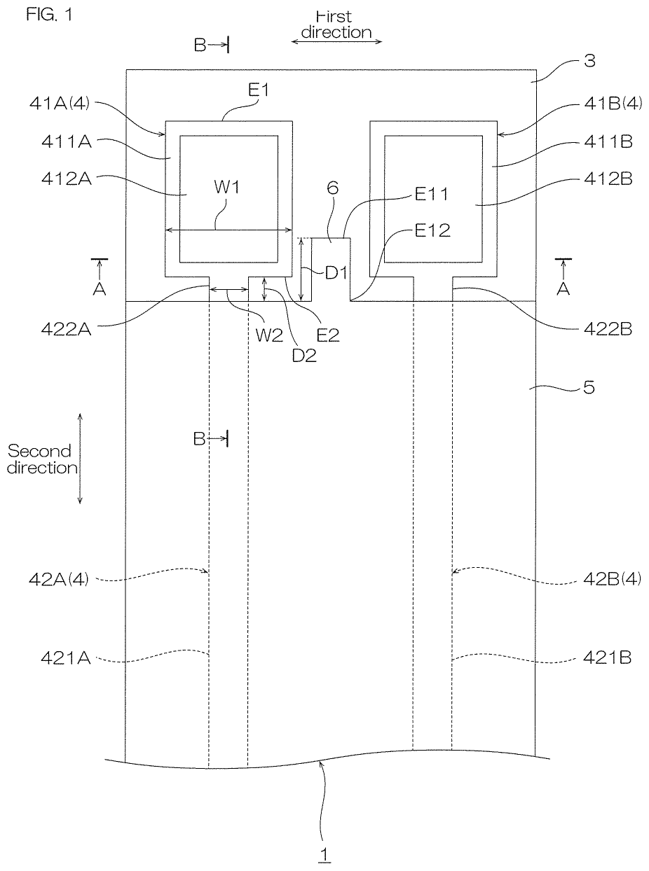

As shown in FIG. 1, a wiring circuit board 1 extends in a first direction and a second direction. The first direction is a direction in which a first terminal 41A and a second terminal 41B, both of which are described later, are arranged. The second direction is orthogonal to the first direction. The shape of the wiring circuit board 1 is not limited. The wiring circuit board 1 may be a flexible wiring circuit board or a suspension board with circuit.

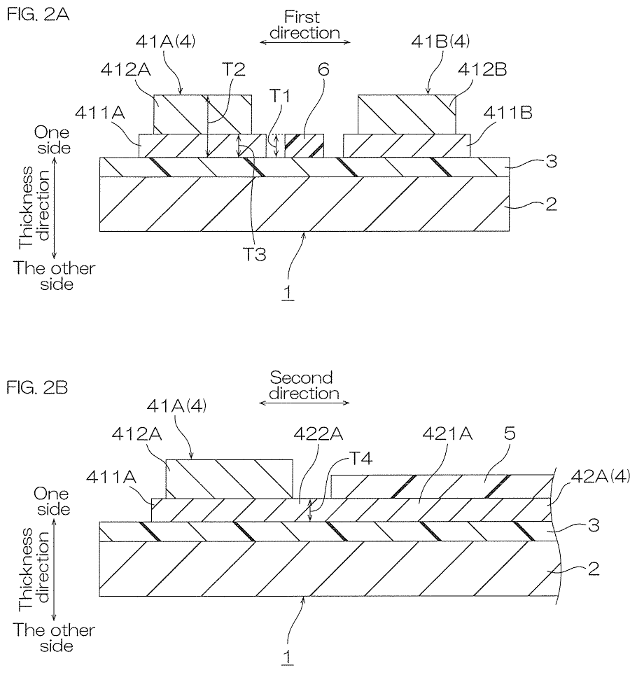

As shown in FIG. 2A, the wiring circuit board 1 includes a metal support layer 2, a first insulating layer 3, a circuit pattern 4, a second insulating layer 5 (see FIG. 1), and a third insulating layer 6.

### (1) Metal Support Layer

The metal support layer 2 supports the first insulating layer 3, the circuit pattern 4, the second insulating layer 5, and the third insulating layer 6. Examples of the material of the metal support layer 2 include stainless steel and a copper alloy.

### (2) First Insulating Layer

The first insulating layer 3 is disposed on one side of the metal support layer 2 in a thickness direction of the metal support layer 2. The thickness direction is orthogonal to the first direction and the second direction. The first insulating layer 3 is disposed on a one-side surface of the metal support layer 2 in the thickness direction. The first insulating layer 3 is disposed between the metal support layer 2 and the circuit pattern 4 in the thickness direction. The first insulating layer 3 insulates the metal support layer 2 from the circuit pattern 4. The first insulating layer 3 is made of resin. Examples of the resin include polyimide, maleimide, epoxy resin, polybenzoxazole, and polyester. Preferably, the first insulating layer 3 is made of polyimide.

### (3) Circuit Pattern

The circuit pattern 4 is disposed on one side of the first insulating layer 3 in the thickness direction. The circuit pattern 4 is disposed on a one-side surface of the first insulating layer 3 in the thickness direction. The circuit pattern 4 is disposed on the opposite side to the metal support layer 2 with respect to the first insulating layer 3 in the thickness direction.

As shown in FIG. 1, the circuit pattern 4 includes a first terminal 41A, a second terminal 41B, a first wire 42A, and a second wire 42B.

### (3-1) First Terminal

The first terminal 41A is disposed in one end portion of the wiring circuit board 1 in the second direction. The first terminal 41A includes a first conductor layer 411A and a second conductor layer 412A.

The first conductor layer 411A is disposed on the one-side surface of the first insulating layer 3 in the thickness direction. The first conductor layer 411A extends in the first direction and the second direction. The first conductor layer 411A has a substantially rectangular board shape. In other words, the first conductor layer 411A has a square land-shape. The first conductor layer 411A has a first edge E1 and a second edge E2 in the second direction. The first edge E1 is disposed away from a first exposed portion 422A of the first wire 42A in the second direction. The first exposed portion 422A is described later. The first edge E1 extends in the first direction. The second edge E2 is disposed between the first edge E1 and the first exposed portion 422A in the second direction. The second edge E2 extends in the first direction. The first conductor layer 411A is made of metal. Examples of the metal include, for example, copper, silver, gold, iron, aluminum, and the alloys thereof. The first conductor layer 411A is preferably made of copper.

As shown in FIG. 2B, the second conductor layer 412A is disposed on one side of the first conductor layer 411A in the thickness direction. The second conductor layer 412A is disposed on a one-side surface of the first conductor layer 411A. The second conductor layer 412A may be thicker than the first conductor layer 411A. The second conductor layer 412A protrudes toward the opposite side to the first insulating layer 3 with respect to the first conductor layer 411A in the thickness direction of the first insulating layer 3, as compared with the second insulating layer 5. The material of the second conductor layer 412A may be the same metal as the material of the first conductor layer 411A. The second conductor layer 412A is preferably made of the same metal as that of the first conductor layer 411A.

### (3-2) Second Terminal

As shown in FIG. 1, the second terminal 41B is disposed in one end portion of the wiring circuit board 1 in the second direction. The second terminal 41B is spaced apart from the first terminal 41A in the first direction. The second terminal 41B has the same layer-structure as that of the first terminal 41A. That is, the second terminal 41B includes a first conductor layer 411B and a second conductor layer 412B in the same manner as the first terminal 41A.

The description of the first conductor layer 411B is the same as the description of the first conductor layer 411A, and the description of the second conductor layer 412B is the same as the description of the second conductor layer 412A. Therefore, the description of the first conductor layer 411B and the description of the second conductor layer 412B are omitted.

### (3-3) First Wire

The first wire 42A is connected to the first terminal 41A. Specifically, the first wire 42A is connected to the first conductor layer 411A of the first terminal 41A. The first wire 42A is made of the same metal as that of the first conductor layer 411A. The first wire 42A includes a first body portion 421A and the first exposed portion 422A.

The first body 421A is a part of the first wire 42A that is covered by the second insulating layer 5. The first body portion 421A is disposed away from the first terminal 41A. The shape of the first body portion 421A is not limited. In the present embodiment, the first body portion 421A extends in the second direction. The first body portion 421A may be bent toward the first direction.

When the total length of the first wire 42A is 100%, the length of the first body portion 421A is, for example, 50% to 99.99%. This ratio may be 99.0% or less, or may be 95.0% or less.

The first exposed portion 422A is a part of the first wire 42A that is exposed from the second insulating layer 5. The first exposed portion 422A is disposed between the first terminal 41A and the first body portion 421A. The first exposed portion 422A is disposed in a central portion of the first terminal 41A in the first direction. The first exposed portion 422A is continuous with the first body portion 421A and is connected to the second edge E2 of the first terminal 41A. The first exposed portion 422A extends in the second direction. Here, when the solder placed on the first terminal 41A melts, there is a possibility that the molten solder flows along the first exposed portion 422A. In this regard, the first exposed portion 422A extends in the second direction, and thus the molten solder can be guided in the second direction. Consequently, it is possible to suppress the flow of the molten solder toward the second terminal 41B in the first direction.

A width W2 (dimension in the first direction) of the first exposed portion 422A is narrower than a width W1 (dimension in the first direction) of the first terminal 41A. Therefore, even when the molten solder flows along the first exposed portion 422A, the flowing solder can be concentrated in the first direction in a range narrower than the width W1 of the first terminal 41A. Consequently, it is possible to suppress the flow of the molten solder toward the second terminal 41B in the first direction.

### (3-4) Second Wire

The second wire 42B is connected to the second terminal 41B. Specifically, the second wire 42B is connected to the first conductor layer 411B of the second terminal 41B. The second wire 42B is made of the same metal as that of the first conductor layer 411B. The second wire 42B is disposed away from the first wire 42A. The second wire 42B has a second body portion 421B and a second exposed portion 422B.

The second body portion 421B is a part of the second wire 42B that is covered by the second insulating layer 5. The second body portion 421B is disposed away from the second terminal 41B. The shape of the second body portion 421B is not limited. In the present embodiment, the second body portion 421B extends in the second direction. The second body portion 421B may be bent toward the first direction.

When the total length of the second wire 42B is 100%, the length of the second body portion 421B is, for example, 50% to 99.99%. This ratio may be 99.0% or less, or 95.0% or less.

The second exposed portion 422B is a part of the second wire 42B that is exposed from the second insulating layer 5. The second exposed portion 422B is disposed between the second terminal 41B and the second body portion 421B. The second exposed portion 422B is disposed in a central portion of the second terminal 41B in the first direction. The second exposed portion 422B is continuous with the second body portion 421B and connected to the second terminal 41B. The second exposed portion 422B extends in the second direction. The width (dimension in the first direction) of the second exposed portion 422B is narrower than the width (dimension in the first direction) of the second terminal 41B.

### (4) Secondary Insulating Layer

The second insulating layer 5 is disposed on the one-side surface of the first insulating layer 3 in the thickness direction. The second insulating layer 5 covers the first wire 42A and the second wire 42B. Specifically, the second insulating layer 5 covers the first body portion 421A of the first wire 42A and the second body portion 421B of the second wire 42B. The second insulating layer 5 does not cover the first terminal 41A, the second terminal 41B, the first exposed portion 422A of the first wire 42A, and the second exposed portion 422B of the second wire 42B. The second insulating layer 5 is made of resin. Examples of the resin include polyimide, maleimide, epoxy resin, polybenzoxazole, and polyester.

### (5) Third Insulating Layer

The third insulating layer 6 is disposed between the first exposed portion 422A and the second terminal 41B, and is disposed between the first terminal 41A and the second terminal 41B in the first direction.

Therefore, even when the solder placed on the first terminal 41A melts, and the molten solder flows from the first terminal 41A and the first exposed portion 422A toward the second terminal 41B, the molten solder can be stopped by the third insulating layer 6. Consequently, it is possible to suppress a short circuit between the first terminal 41A and the second terminal 41B caused by the solder.

Furthermore, the third insulating layer 6 is disposed between the first exposed portion 422A and the second exposed portion 422B. Therefore, even when the solder flowing along the first exposed portion 422A flows along the edge of the second insulating layer 5 toward the second exposed portion 422B, the molten solder can be stopped by the third insulating layer 6. Consequently, it is also possible to suppress a short circuit between the first exposed portion 422A and the second exposed portion 422B caused by the solder.

The third insulating layer 6 extends in the second direction. The third insulating layer 6 has one end portion E11 and the other end portion E12 in the second direction. In the second direction, a distance D1 between the one end portion E11 and the second insulating layer 5 is longer than a distance D2 between the second edge E2 of the first terminal 41A and the second insulating layer 5. The other end portion E12 is disposed between the one end portion E11 and the second insulating layer 5 in the second direction. The other end portion E12 of the third insulating layer 6 is preferably continuous with the second insulating layer 5. Since the other end portion E12 of the third insulating layer 6 is continuous with the second insulating layer 5, the solder flowing from the first exposed portion 422A toward the second exposed portion 422B can surely be stopped.

The third insulating layer 6 is disposed away from the first terminal 41A and the second terminal 41B in the first direction. Therefore, the solder flowing from the first terminal 41A or the first exposed portion 422A toward the second terminal 41B can be received between the third insulating layer 6 and the first terminal 41A. Further, the solder flowing from the second terminal 41B or the second exposed portion 422B toward the first terminal 41A can be received between the third insulating layer 6 and the second terminal 41B.

As shown in FIG. 2A, the third insulating layer 6 is disposed on one side of the first insulating layer 3 in the thickness direction. The third insulating layer 6 is disposed on the one- side surface of the first insulating layer 3 in the thickness direction.

A thickness T1 of the third insulating layer 6 may be smaller than a thickness T2 of the first terminal 41A. The thickness T1 of the third insulating layer 6 is preferably equal to or larger than a thickness T3 of the first conductor layer 411A. The thickness T1 of the third insulating layer 6 is preferably equal to or larger than a thickness T4 (see FIG. 2B) of the first exposed portion 422A.

### 2. Operations and Effects

(1) According to the wiring circuit board 1, as shown in FIG. 1, the third insulating layer 6 is disposed between the first exposed portion 422A and the second terminal 41B in the first direction, and is disposed between the first terminal 41A and the second terminal 41B.

Therefore, even when the solder placed on the first terminal 41A melts, and the molten solder flows from the first terminal 41A and the first exposed portion 422A toward the second terminal 41B, the molten solder can be stopped by the third insulating layer 6.

Consequently, it is possible to suppress a short circuit between the first terminal 41A and the second terminal 41B caused by the solder.
(2) According to the wiring circuit board 1, as shown in FIG. 1, the third insulating layer 6 is disposed between the first exposed portion 422A and the second exposed portion 422B.

Therefore, even when the solder flowing along the first exposed portion 422A flows along the edge of the second insulating layer 5 toward the second exposed portion 422B, the molten solder can be stopped by the third insulating layer 6.

Consequently, it is possible to suppress a short circuit between the first exposed portion 422A and the second exposed portion 422B caused by the solder.
(3) According to the wiring circuit board 1, as shown in FIG. 1, the other end portion E12 of the third insulating layer 6 is continuous with the second insulating layer 5.

Therefore, the solder flowing from the first exposed portion 422A toward the second exposed portion 422B can surely be stopped.
(4) According to the wiring circuit board 1, as shown in FIG. 1, the first exposed portion 422A extends in the second direction.

Therefore, the molten solder can be guided in the second direction.

Consequently, it is possible to suppress the flow of the molten solder in the first direction toward the second terminal 41B.
(5) According to the wiring circuit board 1, as shown in FIG. 1, the width W2 of the first exposed portion 422A is narrower than the width W1 of the first terminal 41A.

Therefore, even when the molten solder flows along the first exposed portion 422A, the flowing solder can be concentrated in a range narrower than the width W1 of the first terminal 41A in the first direction.

Consequently, it is possible to suppress the flow of the molten solder in the first direction toward the second terminal 41B.

### 3. Modified Examples

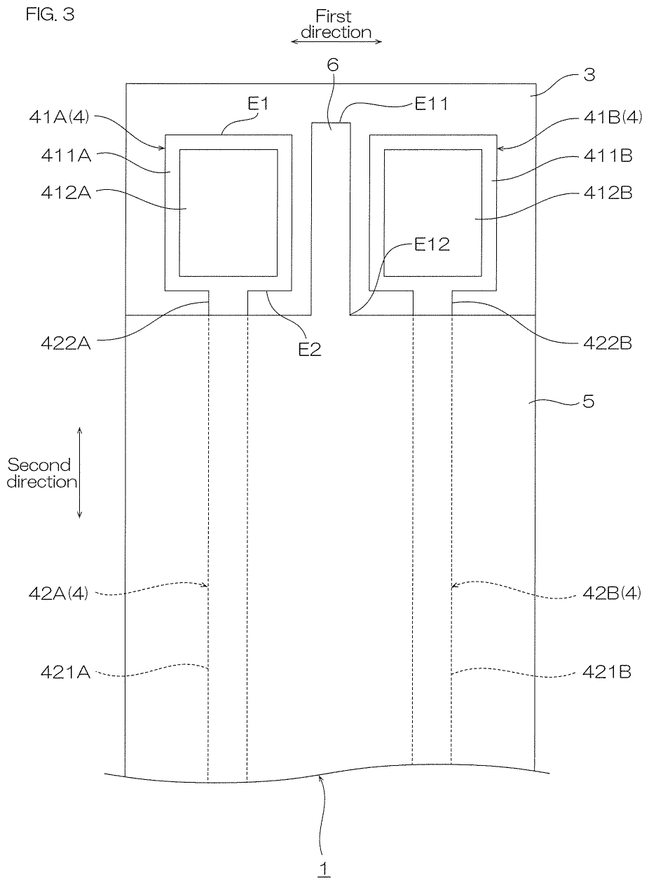

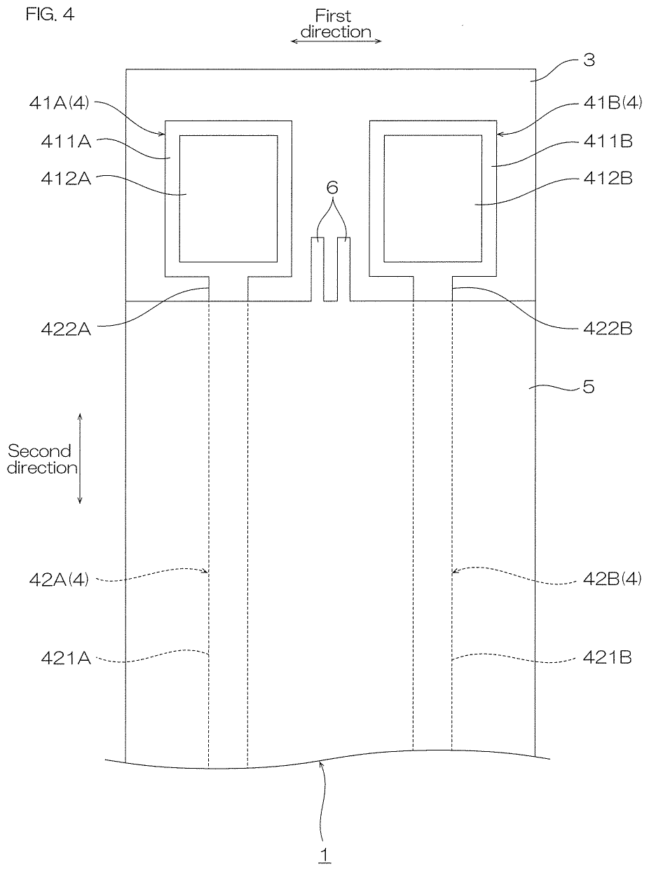

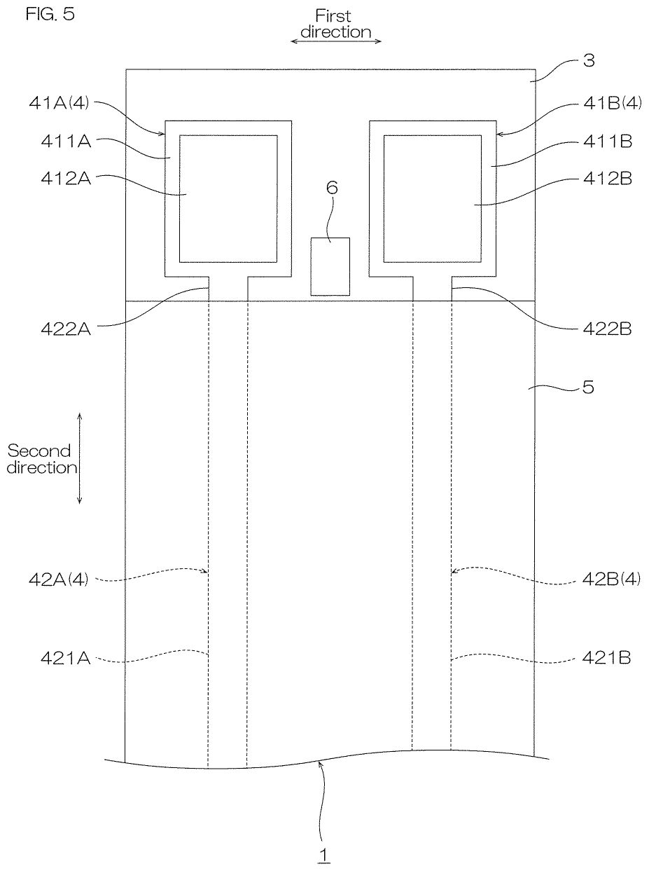

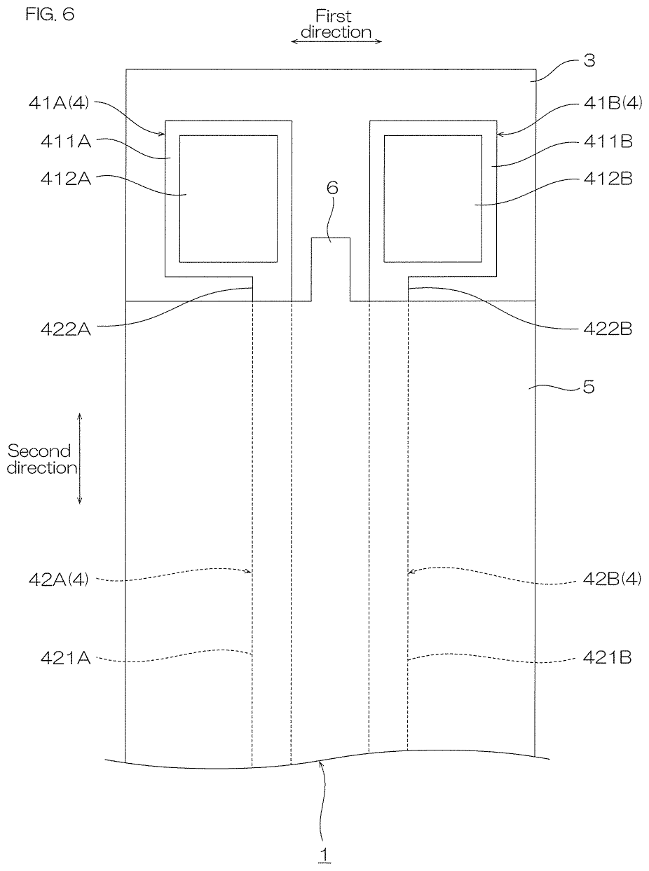

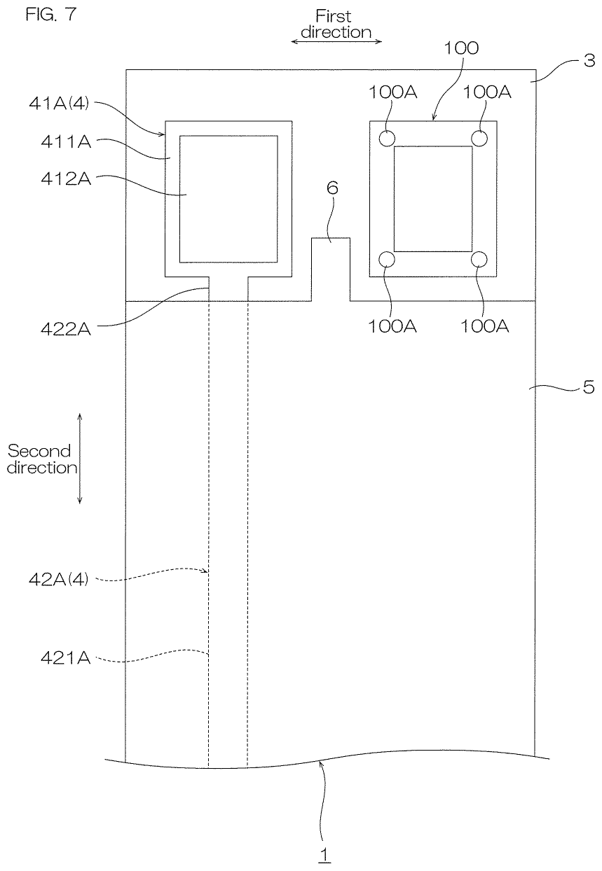

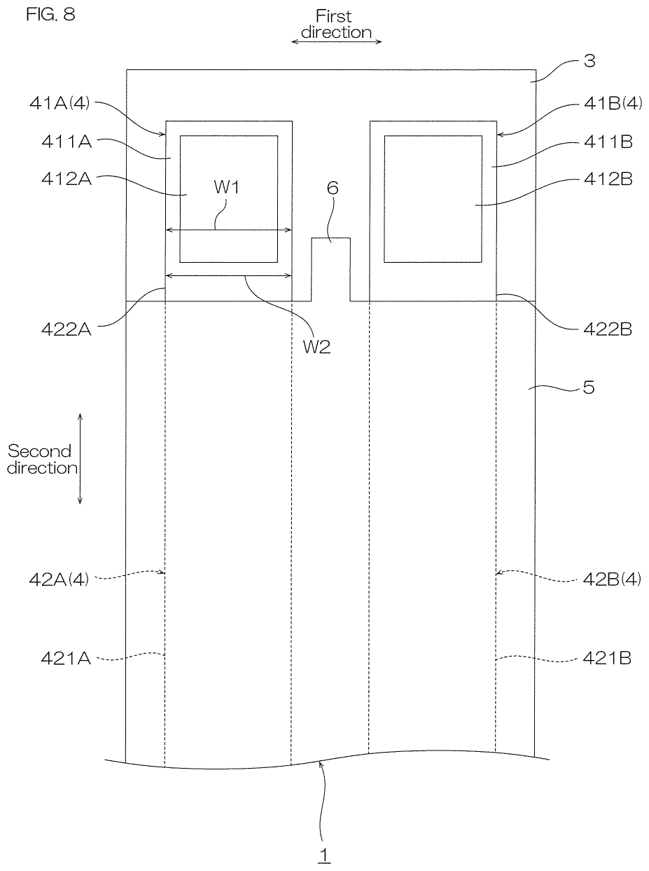

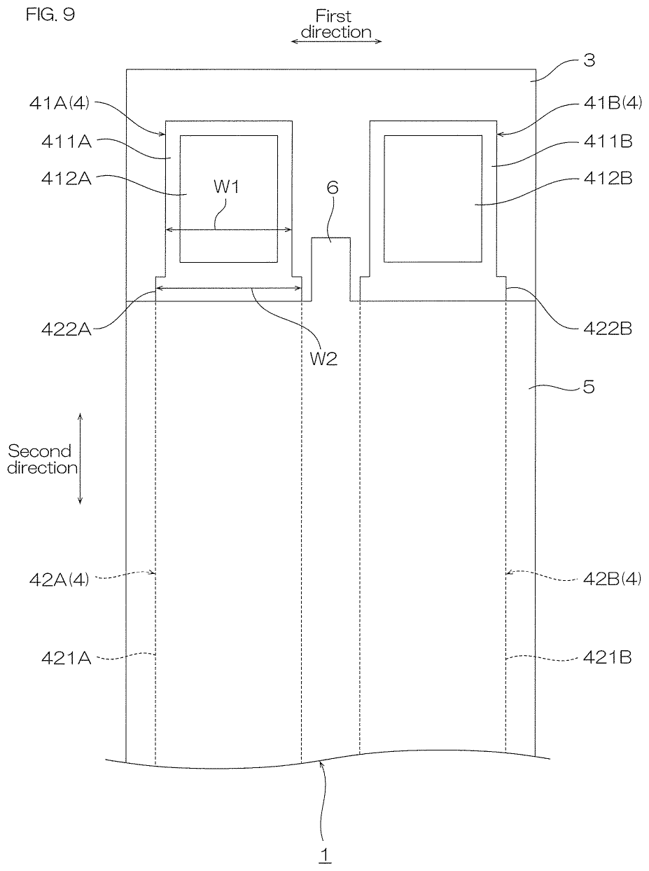

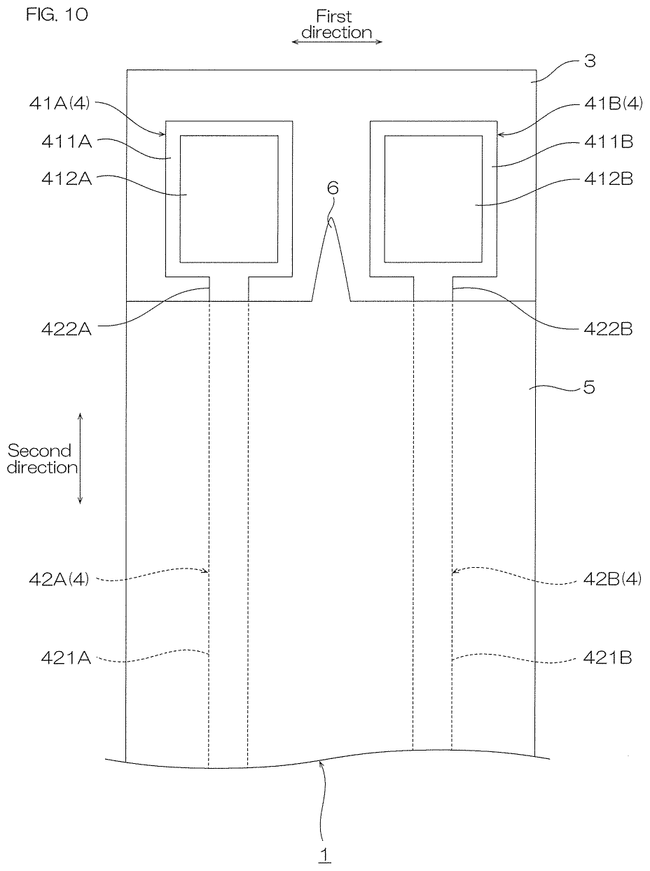

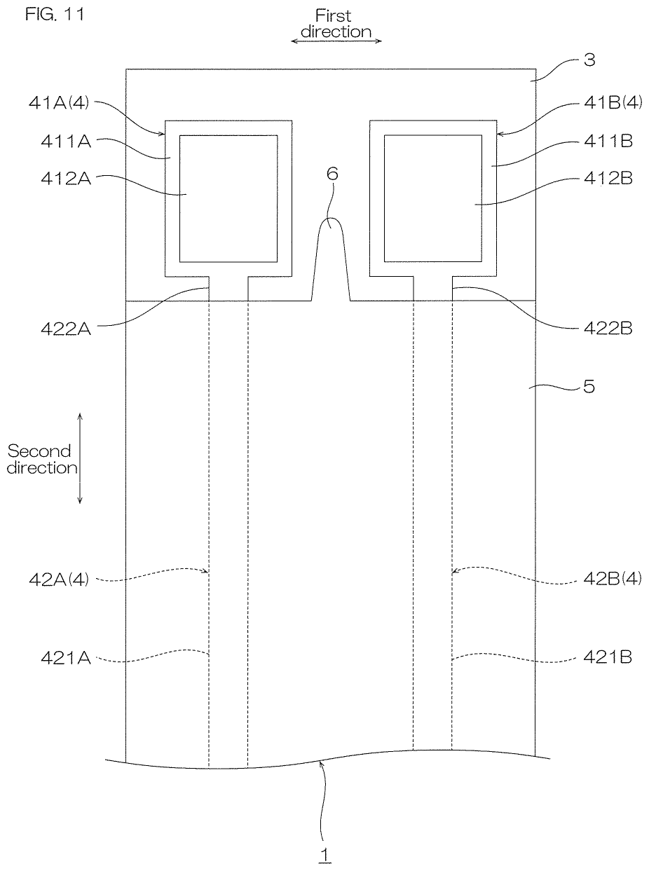

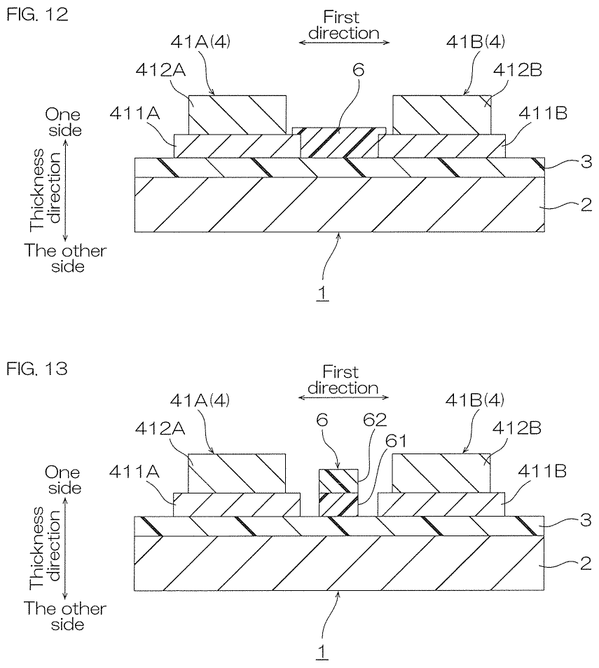

Modified examples are described. In the modified examples, the same members as in the above-described embodiment are given the same numerical references and the descriptions thereof are omitted.
(1) As shown in FIG. 3, the third insulating layer 6 may be disposed between the entire first terminal 41A and the entire second terminal 41B in the first direction. The third insulating layer 6 may extend to the opposite side to the second insulating layer 5 with respect to the first edge E1 of the first terminal 41A in the second direction. In other words, the one end portion E11 of the third insulating layer 6 may be disposed on the opposite side to the second insulating layer 5 with respect to the first end E1 of the first terminal 41A in the second direction. The one end portion E11 of the third insulating layer 6 may be disposed at the same position as the first edge E1 of the first terminal 41A in the second direction.
(2) As shown in FIG. 4, a plurality of third insulating layers 6 may be disposed between the first terminal 41A and the second terminal 41B in the first direction.
(3) As shown in FIG. 5, the third insulating layer 6 may not be continuous with the second insulating layer 5. In this case, the third insulating layer 6 may be separated from the second insulating layer 5 in the second direction, to the extent that the solder is not allowed to pass therebetween. The third insulating layer 6 may not be continuous with the second insulating layer 5 and may be in contact with the second insulating layer 5 in the second direction.
(4) As shown in FIG. 6, the first exposed portion 422A may be disposed closer to the second terminal 41B than the central of the first terminal 41A in the first direction. The second exposed portion 422B may be disposed closer to the first terminal 41A than the central of the second terminal 41B in the first direction.
(5) As shown in FIG. 7, a second terminal 100 may be a ground terminal. The second terminal 100 is electrically connected to the metal support layer 2 (see FIG. 2A) through a via 100A.
(6) As shown in FIG. 8, the width W2 of the first exposed portion 422A may be the same as the width W1 of the first terminal 41A. Further, as shown in FIG. 9, the width W2 of the first exposed portion 422A may be larger than the width W1 of the first terminal 41A.
(7) The shape of the third insulating layer 6 is not limited. For example, as shown in FIG. 10, the third insulating layer 6 may have a tapered shape that becomes narrower as it goes away from the second insulating layer 5 in the second direction. As shown in FIG. 11, the third insulating layer 6 may have a parabolically tapered shape. The third insulating layer 6 may have an exponentially tapered shape.
(8) As shown in FIG. 12, the third insulating layer 6 may cover an edge of the first terminal 41A and an edge of the second terminal 41B. As shown in FIG. 13, the third insulating layer 6 may be a laminate of a plurality of insulating layers 61 and 62.

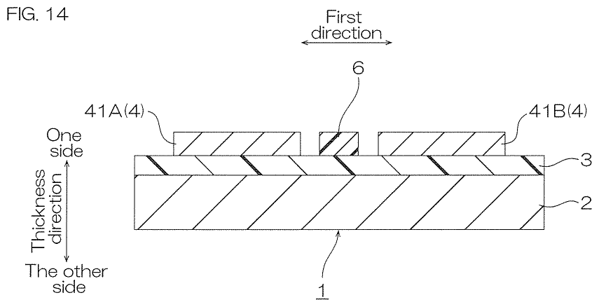

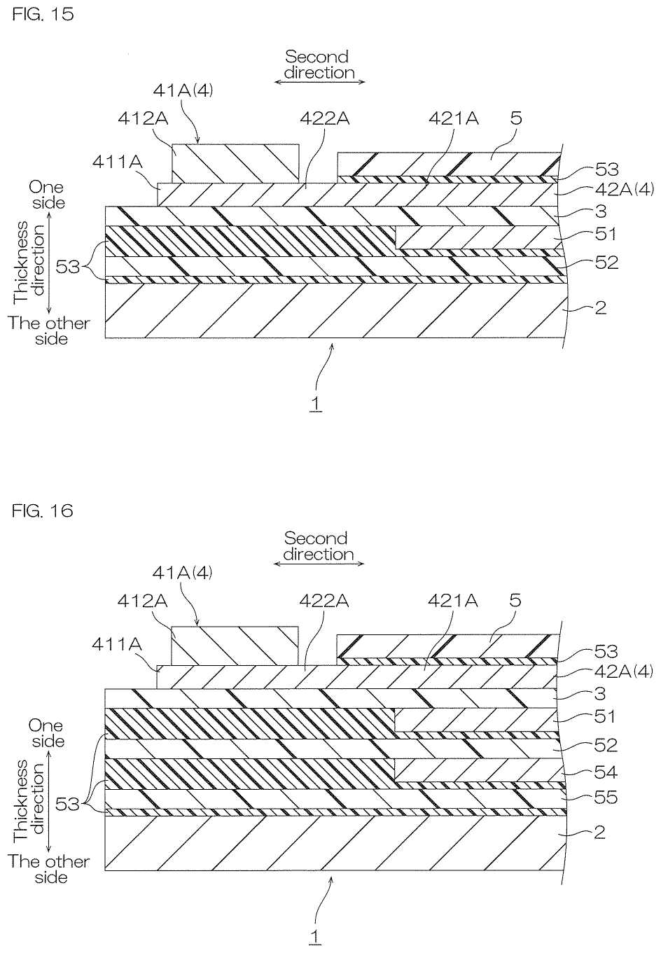

Further, the wiring circuit board 1 may include a conductor layer disposed between the first exposed portion 422A and the second terminal 41B and disposed between the first terminal 41A and the second terminal 41B, and the third insulating layer 6 may cover the conductor layer.
(9) As shown in FIG. 14, the first terminal 41A and the second terminal 41B may be formed from a one-layer conductor layer.
(10) The first terminal 41A and the second terminal 41B may be plated.
(11) As shown in FIG. 15, the wiring circuit board 1 may further include a third conductor layer 51 and a third insulating layer 52.

The third conductor layer 51 is disposed on the other side of the first insulating layer 3 in the thickness direction. The third conductor layer 51 is disposed on an other-side surface of the first insulating layer 3 in the thickness direction. The third conductor layer 51 is disposed on the opposite side to the circuit pattern 4 with respect to the first insulating layer 3 in the thickness direction.

The third insulating layer 52 covers the third conductor layer 51. The third insulating layer 52 is disposed on the other side of the first insulating layer 3 in the thickness direction. The third insulating layer 52 is disposed on the other-side surface of the first insulating layer 3 in the thickness direction. The third insulating layer 52 may be bonded to the other-side surface of the first insulating layer 3 and the third conductor layer 51 in the thickness direction with an adhesive 53. The third insulating layer 52 may be in direct contact with the other-side surface of the first insulating layer 3 and the third conductor layer 51 in the thickness direction. Specifically, when the third insulating layer 52 also functions as an adhesive, the third insulating layer 52 can be directly bonded to the other-side surface of the first insulating layer 3 and the third conductor layer 51. For example, when the third insulating layer 52 is a thermoplastic resin, the third insulating layer 52 may also function as an adhesive.

Further, the second insulating layer 5 may be bonded to the one-side surface of the first insulating layer 3 and each of the wires (the first wire 42A and the second wire 42B) in the thickness direction with the adhesive 53.

Furthermore, the metal support layer 2 may be bonded to an other-side surface of the third insulating layer 52 in the thickness direction with the adhesive 53. When the third insulating layer 52 also functions as an adhesive, the metal support layer 2 may be directly bonded to the third insulating layer 52. In other words, the third insulating layer 52 may bond the other-side surface of the first insulating layer 3 to the metal support layer 2, and may also bond the third conductor layer 51 to the metal support layer 2.
(12) As shown in FIG. 16, the wiring circuit board 1 may further include a fourth conductor layer 54 and a fourth insulating layer 55 in addition to the third conductor layer 51 and the third insulating layer 52. In this case, the wiring circuit board 1 may not include a third conductor layer 51.

The fourth conductor layer 54 is disposed on the other side of the third insulating layer 52 in the thickness direction. The fourth conductor layer 54 is disposed on the other-side surface of the third insulating layer 52 in the thickness direction. The fourth conductor layer 54 is disposed on the opposite side to the third conductor layer 51 with respect to the third insulating layer 52 in the thickness direction.

The fourth insulating layer 55 covers the fourth conductor layer 54. The fourth insulating layer 55 is disposed on the other side of the third insulating layer 52 in the thickness direction. The fourth insulating layer 55 is disposed on the other-side surface of the third insulating layer 52 in the thickness direction. The fourth insulating layer 55 may be bonded to the other-side surface of the third insulating layer 52 and the fourth conductor layer 54 in the thickness direction with the adhesive 53. The fourth insulating layer 55 may be in direct contact with the other-side surface of the third insulating layer 52 and the fourth conductor layer 54 in the thickness direction. Specifically, when the fourth insulating layer 55 also functions as an adhesive, the fourth insulating layer 55 can be directly bonded to the other-side surface of the third insulating layer 52 and the fourth conductor layer 54. For example, when the fourth insulating layer 55 is a thermoplastic resin, the fourth insulating layer 55 may also function as an adhesive.

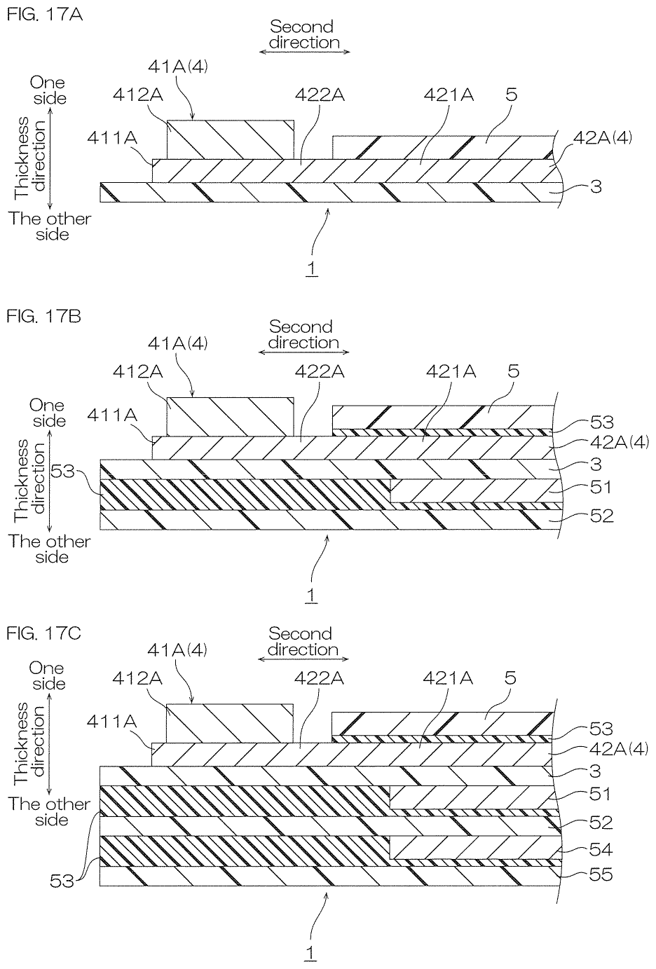

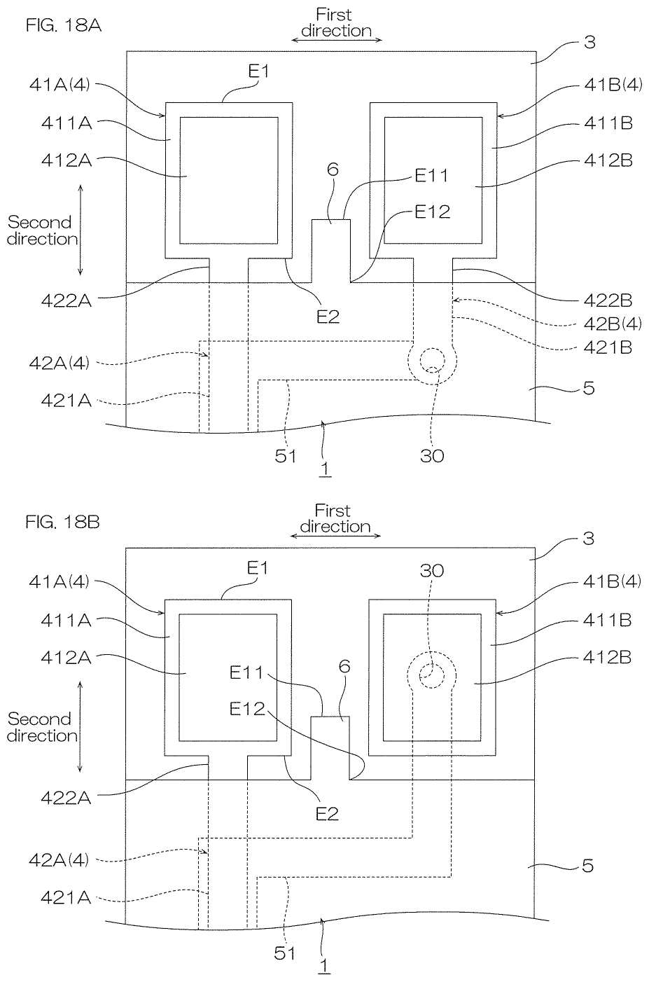

The metal support layer 2 may be bonded to the other-side surface of the fourth insulating layer 55 in the thickness direction with the adhesive 53. When the fourth insulating layer 55 also functions as an adhesive, the metal support layer 2 may be directly bonded to the fourth insulating layer 55. In other words, the fourth insulating layer 55 may bond the other-side surface of the third insulating layer 52 to the metal support layer 2, and may bond the fourth conductor layer 54 to the metal support layer 2.
(13) As shown in FIGS. 17A to 17C, the wiring circuit board 1 may not include a metal support layer 2. Specifically, as shown in FIG. 17A, the wiring circuit board 1 shown in FIG. 2B may not include a metal support layer 2. As shown in FIG. 17B, the wiring circuit board 1 shown in FIG. 15 may not include a metal support layer 2. As shown in FIG. 17C, the wiring circuit board 1 shown in FIG. 16 may not include a metal support layer 2.
(14) As shown in FIGS. 18A and 18B, when the wiring circuit board 1 includes a third conductor layer 51, for example, the second terminal 41B may be electrically connected to the third conductor layer 51.

Specifically, as shown in FIG. 18A, the second wire 42B may be connected to the third conductor layer 51 through a penetrating hole 30 (via hole) of the first insulating layer 3. In this manner, the second terminal 41B is electrically connected to the third conductor layer 51 through the second wire 42B.

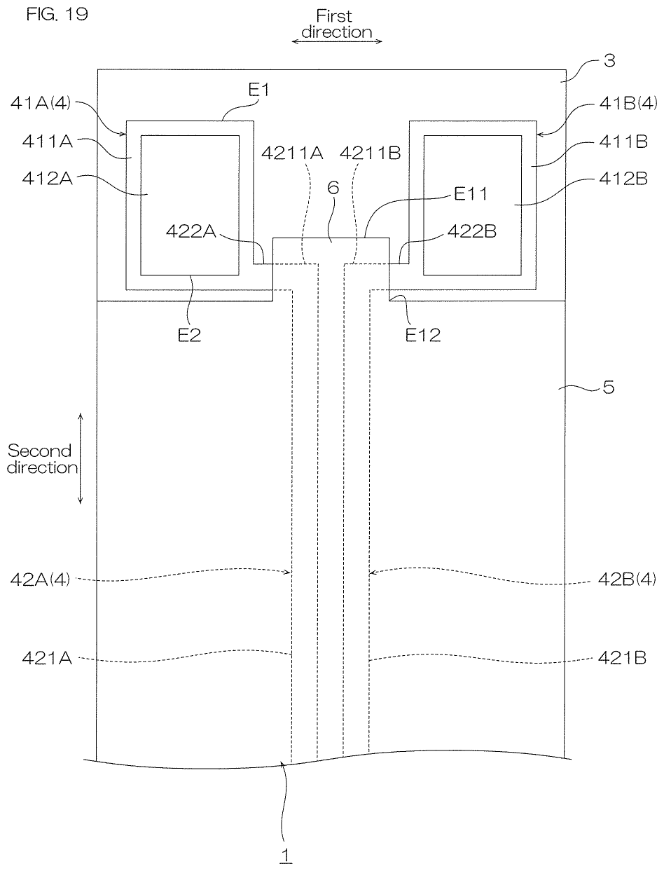

Further, as shown in FIG. 18B, the second terminal 41B may be directly connected to the third conductor layer 51 through a penetrating hole 30 (via hole) of the first insulating layer 3. In this case, the wiring circuit board 1 does not include a second wire 42B.
(15) As shown in FIG. 19, the first exposed portion 422A of the first wire 42A may be disposed between the first terminal 41A and the third insulating layer 6 in the first direction. Further, the second exposed portion 422B of the second wire 42B may be disposed between the second terminal 41B and the third insulating layer 6 in the first direction.

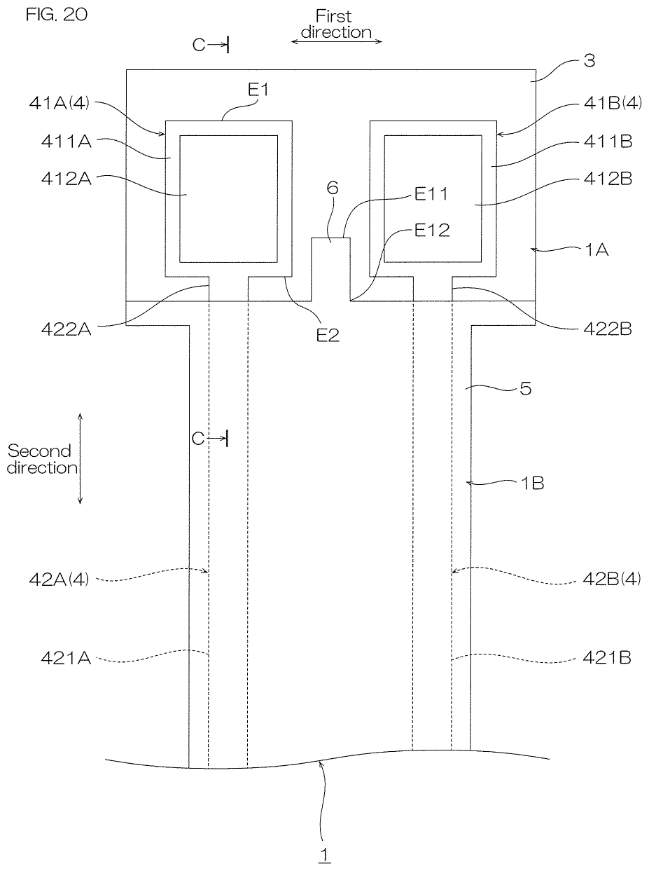

In this case, each of the first exposed portion 422A and the second exposed portion 422B may extend in the first direction. The first body portion 421A may be continuous with the first exposed portion 422A and extend in the first direction, and may be curved toward the second direction. The second body portion 421B may be continuous with the second exposed portion 422B and extend in the first direction, and may be curved toward the second direction. The third insulating layer 6 may cover at least a part of a curved portion 4211A of the first body portion 421A and at least a part of a curved portion 4211B of the second body portion 421B.
(16) As shown in FIG. 20, the wiring circuit board 1 may include a support portion 1A and a flexible portion 1B.

The support portion 1A supports an end portion of the flexible portion 1B. The first terminal 41A and the second terminal 41B may be disposed in the support portion 1A. The support portion 1A may be fixed to an electronic component while the electronic component (not shown) is mounted on the wiring circuit board 1.

The flexible portion 1B is flexible while an electronic component is mounted on the wiring circuit board 1. At least a part of each of the first wire 42A and the second wire 42B is disposed in the flexible portion 1B. The shape of each of the first wire 42A and the second wire 42B in the flexible portion 1B is not limited. Each of the first wire 42A and the second wire 42B in the flexible portion 1B may be straight or curved. The wiring circuit board 1 may include a plurality of flexible portions 1B.

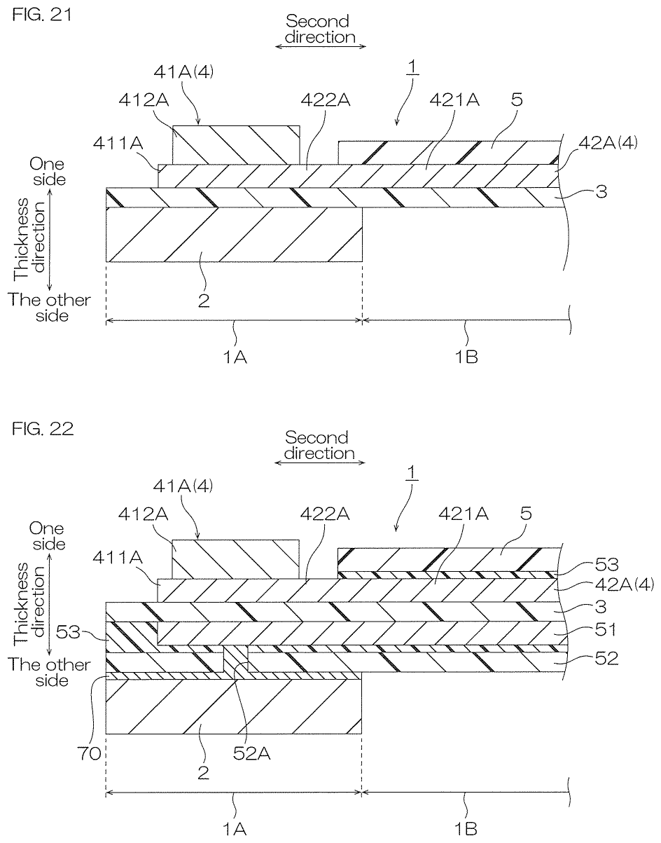

In this case, as shown in FIG. 21, the metal support layer 2 may not be disposed in the flexible portion 1B but may be disposed in the support portion 1A. In other words, the support portion 1A may include a metal support layer 2, and the flexible portion 1B may not include a metal support layer 2.
(17) As shown in FIG. 22, when the wiring circuit board 1 includes a support portion 1A and a flexible portion 1B, the wiring circuit board 1 may include a third conductor layer 51 and a third insulating layer 52.

In this case, the metal support layer 2 may be bonded to the third insulating layer 52 with an adhesive 70. The adhesive 70 is a conductive adhesive, and may be in contact with the third conductor layer 51 through a penetrating hole 52A of the third insulating layer 52. The third conductor layer 51 may be electrically connected to the metal support layer 2 through the adhesive 70 (conductive adhesive).
(18) Also in the above-described modified examples (1) to (17), the same effects as those of the above-described embodiment can be obtained.

Further, the above-described embodiment and modified examples (1) to (17) can be combined.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### Industrial Applicability

The wiring circuit board of the present invention can be used for connecting electronic components.

### Description of Reference Numerals

1 Wiring circuit board
3 First insulating layer
4 Circuit pattern
41A First terminal
411A First conductor layer
412A Second conductor layer
41B Second terminal
42A First wire
421A First body portion
422A First exposed portion
42B Second wire
421B Second body portion
422B Second exposed portion
5 Second insulating layer
6 Third insulating layer
100 Second terminal

1. A wiring circuit board comprising:
a first insulating layer;
a circuit pattern disposed on the first insulating layer and including a first terminal, a first wire connected to the first terminal, and a second terminal spaced apart from the first terminal;
a second insulating layer disposed on the first insulating layer and covering the first wire; and
a third insulating layer disposed on the first insulating layer,
wherein the first wire includes a first body portion covered with the second insulating layer, and a first exposed portion disposed between the first terminal and the first body portion and exposed from the second insulating layer, and
wherein the third insulating layer is disposed between the first exposed portion and the second terminal, and disposed between the first terminal and the second terminal.

2. The wiring circuit board according to claim 1,
wherein the circuit pattern further includes a second wire connected to the second terminal,
wherein the second wire includes a second body portion covered with the second insulating layer, and a second exposed portion disposed between the second terminal and the second body portion and exposed from the second insulating layer, and
wherein the third insulating layer is disposed between the first exposed portion and the second exposed portion.

3. The wiring circuit board according to claim 1,
wherein the third insulating layer is continuous with the second insulating layer.

4. The wiring circuit board according to claim 1,
wherein the first terminal includes:
a first conductor layer disposed on the first insulating layer; and
a second conductor layer disposed on the first conductor layer.

5. The wiring circuit board according to claim 4,
wherein the second conductor layer protrudes toward an opposite side to the first insulating layer with respect to the first conductor layer in the thickness direction of the first insulating layer, as compared with the second insulating layer.

6. The wiring circuit board according to claim 1,
wherein the third insulating layer is disposed away from the first terminal and the second terminal.

7. The wiring circuit board according to claim 1,
wherein the first exposed portion extends in a direction orthogonal to a direction in which the first terminal and the second terminal are arranged.

8. The wiring circuit board according to claim 1,
wherein a width of the first exposed portion is narrower than a width of the first terminal.

9. The wiring circuit board according to claim 1, comprising: a flexible portion in which at least a part of the first wire is disposed; and a support portion that supports the flexible portion,
wherein the support portion includes a metal support layer, and
wherein the flexible portion does not include the metal support layer.
